(19) United States
(12) Patent Application Publication
(10) Pub. No.: US 2023/0178383 A1
(43) Pub. Date: Jun. 8, 2023

(54) RELEASE FILM FOR SEMICONDUCTOR PACKAGE AND MANUFACTURING METHOD THEREFOR

(71) Applicant: SILTECH CO., LTD., Gyeonggi-do (KR)

(72) Inventors: Goan-Hee Yoon, Gyeonggi-do (KR); Jeong-Eun Lee, Gyeonggi-do (KR)

(21) Appl. No.: 17/922,302

(22) PCT Filed: Jul. 16, 2021
(86) PCT No.: PCT/KR2021/009158

§ 371 Date: Oct. 28, 2022

(30) Foreign Application Priority Data
Jan. 15, 2021 (KR) 10-2021-0006356

(51) Int. Cl. H01L 21/56; C09J 175/04; B32B 27/40

(52) U.S. Cl. CPC H01L 21/566; H01L 21/568; C09J 175/04; B32B 27/40

(57) ABSTRACT

Disclosed are release films for a semiconductor package and manufacturing methods thereof. A release film for a semiconductor package may include a first polyurethane layer portion and a second polyurethane layer portion disposed on the first polyurethane layer portion. The first polyurethane layer portion may have a first surface opposite to the second polyurethane layer portion, and the first surface may have a first fine unevenness for releasability. The second polyurethane layer portion may have a second surface opposite to the first polyurethane layer portion, and the second surface may have a second fine unevenness for releasability. The first and second polyurethane layer portions may include thermosetting polyurethane having cross-linkage. An intermediate layer portion may be further disposed between the first polyurethane layer portion and the second polyurethane layer portion.

### TECHNICAL FIELD

The present invention relates to a polymer-based film member and a manufacturing method thereof, and more particularly, to a release film for a semiconductor package and a manufacturing method thereof.

### BACKGROUND ART

In a packaging process of a semiconductor device, a molding process is a process for encapsulating a chip and a carrier substrate on which the chip is mounted with a molding material. A mold molding apparatus is used to encapsulate a semiconductor device, and an epoxy molding compound (EMC) in which an inorganic material and various auxiliary materials are added to an epoxy resin is mainly used as a molding material. A molding material including a mold resin is injected into a mold die to perform molding.

In the packaging process, a method interposing a release film between the mold and the mold resin may be used as a method of releasing the mold and the molded product after curing of a mold material is completed. The release film is supplied into a molding apparatus, is introduced into a mold which is temperature-controlled to a molding processing temperature, and is closely adhered to the mold by vacuum suction, and a mold resin is filled thereon. Accordingly, the release film may be disposed between the mold and the mold resin. When the mold is opened at the time when the mold resin is cured, the molded product may be peeled off from the release film.

Conventional release films are mainly made by ETFE (ethylene tetrafluoroethylene) resin. The ETFE release film has thermoplasticity and is mainly manufactured according to a T-die ejection method using an extruder. Since the ETFE release film has thermoplastic properties, there is a problem that at a high heating temperature required during the EMC molding process, the release film may not withstand the pressure and the edge portion may be ruptured, which may cause contamination of the mold molding apparatus. Therefore, the ETPE release film has a limitation that it is mainly used at a temperature of about 165° C. or less. Furthermore, when EMC molding is performed using the ETFE release film, since fume-gas generated from EMC has high permeability through the release film, mold contamination is generated due to the fume-gas. As a result of it, a cycle of frequently cleaning the mold is required, and thus there is a problem that productivity is decreased.

### DISCLOSURE OF THE INVENTION

### Technical Problem

An object to be achieved by the present invention is to provide a release film for a semiconductor package which has excellent mechanical properties which may withstand high temperature and high pressure conditions without rupture during a molding process of a semiconductor package, and also has excellent releasability.

Furthermore, the technical object to be achieved by the present invention is to provide a release film for a semiconductor package which may prevent or minimize the problems such as mold contamination due to fume-gas during the molding process of the semiconductor package and a problem that productivity is decreased because of the contamination.

Furthermore, the technical object to be achieved by the present invention is to provide a manufacturing method of the above-described release film for a semiconductor package.

The objects to be solved by the present invention is not limited to the above-mentioned ones, and other objects not mentioned will be understood by those skilled in the art from the following description.

### Technical Solution

According to an embodiment of the present invention, there is provided a release film for a semiconductor package, comprising a first polyurethane layer portion; and a second polyurethane layer portion disposed on the first polyurethane layer portion, wherein the first polyurethane layer portion has a first surface opposite to the second polyurethane layer portion, the first surface has a first fine unevenness for releasability, the second polyurethane layer portion has a second surface opposite to the first polyurethane layer portion, the second surface has a second fine unevenness for releasability, and the first and second polyurethane layer portions include a thermosetting polyurethane having a cross-linkage.

The first surface may have a surface roughness of 5 μm or more due to the first fine unevenness and the second surface may have a surface roughness of 5 μm or more due to the second fine unevenness.

An intermediate layer portion may be further disposed between the first polyurethane layer portion and the second polyurethane layer portion.

The intermediate layer portion may be an adhesive layer.

The adhesive layer may include a urethane-based polymer.

The intermediate layer portion may have the same material composition as the first polyurethane layer portion.

The first polyurethane layer portion and the second polyurethane layer portion may have the same material composition.

The second polyurethane layer portion may have a material composition different from that of the first polyurethane layer portion.

The second polyurethane layer portion may further include an inorganic material, and the second fine unevenness may be formed on the second surface of the second polyurethane layer portion by the inorganic material.

The release film may have, for example, a thickness in a range of about 30 to 120 μm.

A thickness of the first polyurethane layer portion may be, for example, about 10 to 70 μm.

A thickness of the second polyurethane layer portion may be, for example, about 10 to 70 μm.

A thickness of the intermediate layer may be, for example, about 10 to 70 μm.

According to another embodiment of the present invention, there is provided a manufacturing method of a release film for a semiconductor package, comprising: applying a first solution for forming polyurethane on a first matte film, and forming a first polyurethane layer portion from the first solution for forming polyurethane; applying a second solution for forming polyurethane on a second matte film, and forming a second polyurethane layer portion from the second solution for forming the second polyurethane; mutually bonding the first polyurethane layer portion formed on the first matte film and the second polyurethane layer portion formed on the second matte film while interposing an intermediate layer portion therebetween, and forming a bonding structure in which the intermediate layer portion and the second polyurethane layer portion are sequentially disposed on the first polyurethane layer portion; and removing the first matte film from the first polyurethane layer portion, and removing the second matte film from the second polyurethane layer portion, wherein the first polyurethane layer portion has a first surface opposite to the intermediate layer portion, the first surface has a first fine unevenness for releasability, the second polyurethane layer portion has a second surface opposite to the intermediate layer portion, the second surface has a second fine unevenness for releasability, and the first and second polyurethane layer portions include thermosetting polyurethane having a cross-linkage.

The forming the first polyurethane layer portion, the forming the second polyurethane layer portion, and the forming the bonding structure may be performed by using a roll-to-roll process.

The forming the first polyurethane layer portion, the forming the second polyurethane layer portion, and the forming the bonding structure may be performed by using a micro-gravure coater, a comma coater and a slot die coater.

The intermediate layer portion may be an adhesive layer.

The adhesive layer may include a urethane-based polymer.

The intermediate layer portion may have a material composition different from that of the first polyurethane layer portion.

The intermediate layer portion may have the same material composition as the first polyurethane layer portion.

The manufacturing method of the release film may further include applying a first release agent to the first surface of the first polyurethane layer portion and attaching an adhesive film while removing the first matte film from the first polyurethane layer portion; and applying a second release agent to the second surface of the second polyurethane layer portion while removing the second matte film from the second polyurethane layer portion.

According to another embodiment of the present invention, there is provided a manufacturing method of a release film for a semiconductor package, comprising: applying a first solution for forming polyurethane on a matte film, and forming a first polyurethane layer portion from the first solution for forming polyurethane; applying a second solution for forming polyurethane on the first polyurethane layer portion, and forming a second polyurethane layer portion from the second solution for forming polyurethane; and removing the matte film from the first polyurethane layer portion, wherein the first polyurethane layer portion has a first surface opposite to the second polyurethane layer portion, the first surface has a first fine unevenness for releasability, the second polyurethane layer portion has a second surface opposite to the first polyurethane layer portion, the second surface has second unevenness for releasability, and the first and second polyurethane layer portions include thermosetting polyurethane having a cross-linkage.

The forming the first polyurethane layer portion and the forming the second polyurethane layer portion may be performed by using a roll-to-roll process.

The forming the first polyurethane layer portion and the forming the second polyurethane layer portion may be performed by using any one of a micro-gravure coater, a comma coater, and a slot die coater.

After the forming the first polyurethane layer portion, the method of the present invention may further include applying a solution for forming an intermediate layer portion on the first polyurethane layer portion, and forming an intermediate layer portion from the solution for forming the intermediate layer portion, and the second polyurethane layer portion may be formed on the intermediate layer portion.

The intermediate layer portion may have the same material composition as the first polyurethane layer portion.

The second solution for forming polyurethane may include an inorganic material, and the second fine unevenness may be formed on the second surface of the second polyurethane layer portion by the inorganic material.

The inorganic material may include at least one of silica, calcium carbonate (CaCO₃), and barium sulfate (BaSO₄).

The manufacturing method of the release film may further include applying a first release agent to the second surface of the second polyurethane layer portion and attaching an adhesive film; and applying a second release agent to the first surface of the first polyurethane layer portion while removing the matte film from the first polyurethane layer portion.

### Advantageous Effects

According to the embodiments of the present invention, it is possible to implement a release film for a semiconductor package having excellent mechanical properties which may withstand high temperature and high pressure conditions without rupture during a molding process of the semiconductor package, and also having excellent releasability. Furthermore, according to embodiments of the present invention, it is possible to implement a release film for a semiconductor package which may prevent or minimize mold contamination due to fume-gas during a molding process of the semiconductor package, and a problem that productivity is reduced because of the contamination. Furthermore, according to the embodiments of the present invention, the above-described release film may be manufactured by a relatively easy method.

When the release film for a semiconductor package according to the embodiment is used, the defect rate of the semiconductor package may be lowered, productivity may be improved, and characteristics of the manufactured package may be improved.

### BRIEF DESCRIPTION OF THE DRAWINGS

FIG. 1 is a cross-sectional diagram of a release film for a semiconductor package according to an embodiment of the present invention.

FIG. 2 is a cross-sectional diagram of a release film for a semiconductor package according to another embodiment of the present invention.

FIG. 3A to FIG. 3D are cross-sectional diagrams illustrating a method for manufacturing a release film for a semiconductor package according to an embodiment of the present invention.

FIG. 4A to FIG. 4D are cross-sectional diagrams illustrating a method for manufacturing a release film for a semiconductor package according to another embodiment of the present invention.

FIG. 5A to FIG. 5D are cross-sectional diagrams illustrating a method for manufacturing a release film for a semiconductor package according to another embodiment of the present invention.

FIG. 6A to FIG. 6D are cross-sectional diagrams illustrating a method for manufacturing a release film for a semiconductor package according to another embodiment of the present invention.

FIG. 7 is a diagram for explaining an apparatus applicable to a manufacturing method of a release film for a semiconductor package according to an embodiment of the present invention, and a manufacturing process using the same.

FIG. 8A to FIG. 8C are cross-sectional diagrams illustrating manufacturing method of a release film for a semiconductor package according to another embodiment of the present invention.

FIG. 9 is a diagram for explaining a manufacturing method of a release film for a semiconductor package according to another embodiment of the present invention.

FIG. 10 is a diagram for explaining a molding process of a semiconductor package to which a release film for a semiconductor package according to an embodiment of the present invention is applied.

### BEST MODE FOR CARRYING OUT THE INVENTION

Hereinafter, the embodiments of the present invention will be described in detail with reference to the accompanying drawings.

The embodiments of the present invention to be described below are provided to more clearly explain the present invention to those having common knowledge in the related art, and the scope of the present invention is not limited by the following embodiments. The following embodiment may be modified in many different forms.

The terminology used herein is used to describe specific embodiments, and is not used to limit the present invention. As used herein, terms in the singular form may include the plural form unless the context clearly dictates otherwise. Also, as used herein, the terms “comprise” and/or “comprising” specifies presence of the stated shape, step, number, action, member, element and/or group thereof; and does not exclude presence or addition of one or more other shapes, steps, numbers, actions, members, elements, and/or groups thereof. Furthermore, the term “connection” as used herein is a concept that includes not only that certain members are directly connected, but also a concept that other members are further interposed between the members to be indirectly connected.

Furthermore, in the present specification, when a member is said to be located “on” another member, this includes not only a case in which a member is in contact with another member but also a case in which another member is present between the two members. As used herein, the term “and/or” includes any one and any combination of one or more of those listed items. Furthermore, as used herein, terms such as “about”, “substantially”, etc. are used as a range of the numerical value or degree, in consideration of inherent manufacturing and material tolerances, or as a meaning close to the range. Furthermore, accurate or absolute numbers provided to aid the understanding of the present application are used to prevent an infringer from using the disclosed present invention unfairly.

Hereinafter, the embodiments of the present invention will be described in detail with reference to the accompanying drawings. The size or the thickness of the regions or the portions illustrated in the accompanying drawings may be slightly exaggerated for clarity and convenience of description. The same reference numerals refer to the same elements throughout the detailed description.

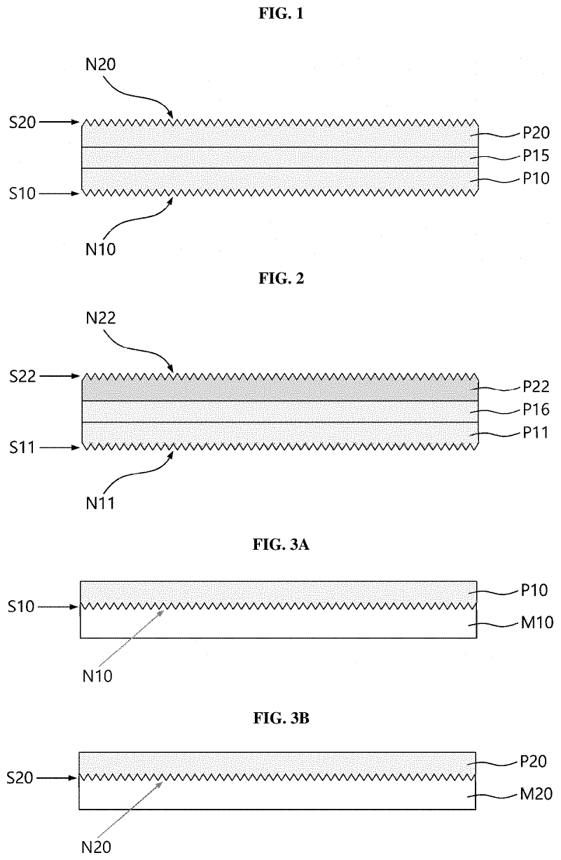

FIG. 1 is a cross-sectional diagram of a release film for a semiconductor package according to an embodiment of the present invention.

Referring to FIG. 1, the release film according to the present embodiment may include a first polyurethane layer portion P10 and a second polyurethane layer portion P20 disposed on the first polyurethane layer portion P10. In an embodiment, an intermediate layer portion P15 may be provided between the first polyurethane layer portion P10 and the second polyurethane layer portion P20.

The first and second polyurethane layer portions P10 and P20 may include thermosetting polyurethane having a cross-linkage. The content of the thermosetting polyurethane in the first polyurethane layer portion P10 may be about 80 wt % or more or about 90 wt % or more. In one embodiment, the content of the thermosetting polyurethane in the first polyurethane layer portion P10 may be about 80 wt % to 100 wt %. Similarly, the content of the thermosetting polyurethane in the second polyurethane layer portion P20 may be about 80 wt % or more or about 90 wt % or more. In one embodiment, the content of the thermosetting polyurethane in the second polyurethane layer portion P20 may be about 80 wt % to 100 wt %. Each of the first and second polyurethane layer portions P10 and P20 may include thermosetting polyurethane as a main constituent material or may be composed of thermosetting polyurethane. Furthermore, depending on the case, at least one of the first and second polyurethane layer portions P10 and P20 may include a polymer material or other additives other than the thermosetting polyurethane, for example, an amount (a small amount) of an initiator (activator) for the crosslinking reaction, a leveling agent and/or an antifoaming agent.

The first polyurethane layer portion P10 may have a first surface S10 on an opposite side of the intermediate layer portion P15, and the first surface S10 may have a first fine unevenness N10 at least for improving releasability. In the drawing, a lower surface of the first polyurethane layer portion P10 may be the first surface S10, and the intermediate layer portion P15 may be bonded to an upper surface of the first polyurethane layer portion P10. The second polyurethane layer portion P20 may have a second surface S20 on an opposite side of the intermediate layer portion P15, and the second surface S20 may have a second fine unevenness N20 at least for improving releasability. In the drawing, an upper surface of the second polyurethane layer portion P20 may be the second surface S20, and the intermediate layer portion P15 may be bonded to a lower surface of the second polyurethane layer portion P20.

The first surface S10 may have a surface roughness Ra of about 5 μm or more due to the first fine unevenness N10. In an embodiment, the surface roughness Ra of the first surface S10 may be about 5 μm to about 20 μm. The second surface S20 may have a surface roughness Ra of about 5 μm or more due to the second fine unevenness N20. In an embodiment, the surface roughness Ra of the second surface S20 may be about 5 μm to about 20 μm. However, the surface roughness Ra of the first surface S10 and the second surface S20 is not limited to the above descriptions, and may be designed differently in some cases.

The intermediate layer portion P15 may be a kind of bonding layer or adhesive layer. The adhesive layer may be used to bond the first polyurethane layer portion P10 and the second polyurethane layer portion P20 to each other. The adhesive layer may include a urethane-based polymer. The urethane-based polymer may be formed by curing a thermosetting urethane resin solution. The urethane-based polymer may include thermosetting polyurethane.

Similar to the first polyurethane layer portion P10 and/or the second polyurethane layer portion P20, the intermediate layer portion P15 may include a urethane-based bonding material containing a urethane bond of an active hydrogen compound including isocyanate or polyol. In an embodiment, the intermediate layer portion P15 may have the same material composition as that of the first polyurethane layer portion P10 and/or the second polyurethane layer portion P20. In some embodiments, the first polyurethane layer portion P10 and the second polyurethane layer portion P20 may have the same material composition. In this case, the first polyurethane layer portion P10, the intermediate layer portion P15, and the second polyurethane layer portion P20 may constitute one integrated layer structure (a base layer structure). However, the intermediate layer portion P15 may have a material composition different from that of at least one of the first polyurethane layer portion P10 and the second polyurethane layer portion P20.

The release film according to an embodiment of the present invention may have a thickness (a total thickness) in a range of about 30 to 120 um. The thickness of the release film may be, for example, about 50 to 100 μ [symbol] m. Under these thickness conditions, the release film may have excellent mechanical properties suitable for a molding process. On the other hand, the thickness of the first polyurethane layer portion P10, for example, may be about 10˜70 [symbol] m, the thickness of the intermediate layer portion P15, for example, may be about 10˜70 [symbol] m, and the thickness of the second polyurethane layer portion P20 may be, for example, about 10˜70 [symbol] m. The thickness of the first polyurethane layer portion P10 may be the same as or similar to the thickness of the second polyurethane layer portion P20. The thickness of the intermediate layer portion P15 may be the same as the thickness of each of the first polyurethane layer portion P10 and the second polyurethane layer portion P20, but may be different. In the latter case, the thickness of the intermediate layer portion P15 may be thinner than the thickness of each of the first polyurethane layer portion P10 and the second polyurethane layer portion P20. When the above thickness conditions are satisfied, it may be advantageous for easy formation (manufacturing) of the release film and improvement of mechanical properties.

FIG. 2 is a cross-sectional diagram of a release film for a semiconductor package according to another embodiment of the present invention.

Referring to FIG. 2, the release film according to this embodiment may include a first polyurethane layer portion P11, an intermediate layer portion P16 disposed on the first polyurethane layer portion P11, and a second polyurethane layer portion P22 disposed on the intermediate layer portion P16. The first and second polyurethane layer portions P11 and P22 may include thermosetting polyurethane having a cross-linkage. The content of the thermosetting polyurethane in the first polyurethane layer portion P11 may be about 80 wt % or more or about 90 wt % or more. In one embodiment, the content of the thermosetting polyurethane in the first polyurethane layer portion P11 may be about 80 wt % to 100 wt %. The content of the thermosetting polyurethane in the second polyurethane layer portion P22 may be about 60 wt % or more or about 80 wt % or more. In one embodiment, the content of the thermosetting polyurethane in the second polyurethane layer portion P22 may be about 60 wt % to 97 wt %, or about 60 wt % to 100 wt %. Each of the first and second polyurethane layer portions P11 and P22 may include thermosetting polyurethane as a main constituent material or may be composed of thermosetting polyurethane. Furthermore, in some cases, at least one of the first and second polyurethane layer portions P11 and P22 may contain some (a small amount) of other polymer materials or other additives (e.g., a leveling agent, an antifoaming agent, etc.) other than the thermosetting polyurethane.

The first polyurethane layer portion P11 may have a first surface S11 on an opposite side of the intermediate layer portion P16, and the first surface S11 may have a first fine unevenness N11 at least for improving releasability. In the drawing, a lower surface of the first polyurethane layer portion P11 may be the first surface S11, and the intermediate layer portion P16 may be bonded to an upper surface of the first polyurethane layer portion P11. The second polyurethane layer portion P22 may have a second surface S22 on an opposite side of the intermediate layer portion P16, and the second surface S22 may have a second fine unevenness N22 at least for improving releasability. In the drawing, an upper surface of the second polyurethane layer portion P22 may be the second surface S22, and the intermediate layer portion P16 may be bonded to a lower surface of the second polyurethane layer portion P22. The range conditions of the surface roughness Ra of each of the first surface S11 and the second surface S22 may be the same as or similar to those described for the first surface S10 and the second surface S20 in FIG. 1.

The intermediate layer portion P16 may have the same material composition as that of the first polyurethane layer portion P11. Accordingly, the first polyurethane layer portion P11 and the intermediate layer portion P16 may form an integrated one-layer structure. Meanwhile, the second polyurethane layer portion P22 may have a material composition different from that of the first polyurethane layer portion P11 and the intermediate layer portion P16. In this case, the second polyurethane layer portion P22 may further include an inorganic material, and the second fine unevenness N22 may be formed on the second surface S22 of the second polyurethane layer portion P22 by the inorganic material. More specifically, the second polyurethane layer portion P22 may include a base layer portion made of thermosetting polyurethane and an inorganic material contained in the base layer portion, and the second fine unevenness N22 may be formed by the inorganic material. The inorganic material may, for example, have a form of particles (a plurality of particles). Furthermore, the inorganic material may include, for example, at least one of silica, calcium carbonate (CaCO₃) and barium sulfate (BaSO₄). However, the type of inorganic material which may be used in the embodiment of the present invention is not limited to the above- mentioned descriptions, and may be variously changed. When the second polyurethane layer portion P22 includes the inorganic material, the inorganic material may be referred to as a kind of filler. In this case, the content of the thermosetting polyurethane with respect to the total amount of the thermosetting polyurethane and the inorganic material in the second polyurethane layer portion P22 may be about 60 wt % or more or about 80 wt % or more. For example, the content of the thermosetting polyurethane with respect to the total amount of the thermosetting polyurethane and the inorganic material in the second polyurethane layer portion P22 may be about 60 wt % to about 97 wt %. The content of the thermosetting polyurethane in the second polyurethane layer portion P22 in the region other than the inorganic material may be about 80 wt % to 100 wt %. In the region other than the inorganic material, the second polyurethane layer portion P22 may include thermosetting polyurethane as a main constituent material or may be composed of thermosetting polyurethane. Furthermore, in some cases, the second polyurethane layer portion P22 may include some (a small amount) of other polymer materials or additives (e.g., a leveling agent, an antifoaming agent, etc.) other than the thermosetting polyurethane.

In the embodiment of FIG. 2, the total thickness of the release film and the thickness range of each of the layer portions P11, P16, and P22 may be the same as or similar to those described with respect to the release film of FIG. 1, and thus repeated description thereof is excluded.

In the release film structure of FIG. 2, the intermediate layer portion P16 may be excluded in some cases. That is, the release film of FIG. 2 may include the first polyurethane layer portion P11, and the second polyurethane layer portion P22 formed thereon without the intermediate layer portion P16. In this case, the second polyurethane layer portion P22 may be in direct contact (bonding) with the upper surface of the first polyurethane layer portion P11.

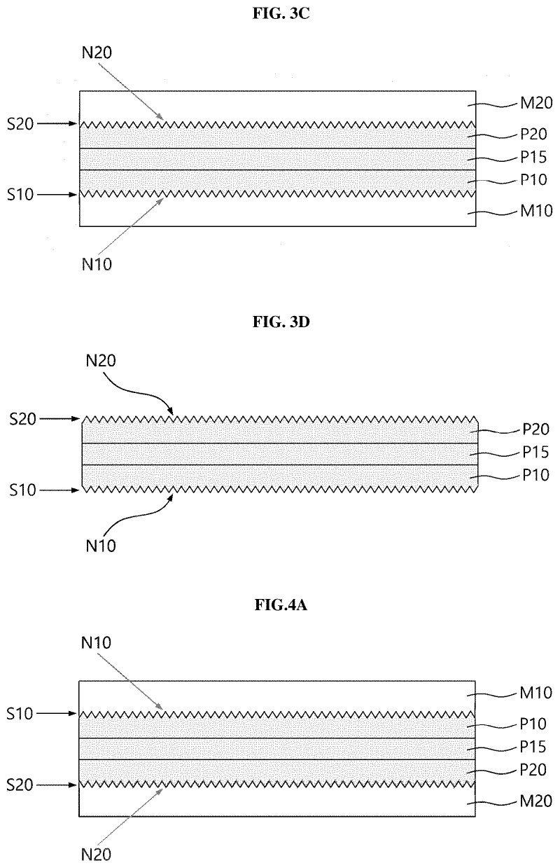

FIG. 3A to FIG. 3D are cross-sectional diagrams illustrating a method for manufacturing a release film for a semiconductor package according to an embodiment of the present invention.

Referring to FIG. 3A, a first solution for forming polyurethane may be applied on a first matte film M10, and a first polyurethane layer portion P10 may be formed from the first solution for forming polyurethane. The first matte film M10 is a matte-treated film, wherein the matte-treatment may refer to a matte process for forming fine unevenness on the surface. The first matte film M10 may be, for example, a polyethylene terephthalate (PET) film, but the material of the first matte film M10 is not limited thereto and may vary.

If the first solution for forming polyurethane is applied on the matte-treated surface (an upper surface in the drawing) of the first matte film M10 and a cured first polyurethane layer portion P10 is formed therefrom, a first fine unevenness N10 may be formed on a first surface S10 of the first polyurethane layer portion P10 bonded to the first matte film M10. It may be mentioned that the shape of the matte-treated surface (an upper surface in the drawing) of the first matte film M10 is transfer to the first surface S10 of the first polyurethane layer portion P10. The first solution for forming polyurethane may include a urethane-based source material, a solvent, and a curing agent, etc.

Referring to FIG. 3B, a second solution for forming polyurethane may be applied on a second matte film M20, and a second polyurethane layer portion P20 may be formed from the second solution for forming polyurethane. The second matte film M20 may be, for example, a PET film, but is not limited thereto, and the material may be variously changed.

If the second solution for forming polyurethane is applied on the mat-treated surface (an upper surface in the drawing) of the second matte film M20 and a cured second polyurethane layer portion P20 is formed therefrom, a second fine unevenness N20 may be formed on a second surface S20 of the second polyurethane layer portion P20 bonded to the second matte film M20. It may be said that a shape of the matte-treated surface (an upper surface in the drawing) of the second matte film M20 is transfer to the second surface S20 of the second polyurethane layer portion P20. The second solution for forming polyurethane may include a urethane-based source material, a solvent, and a curing agent, etc.

Referring to FIG. 3C, the first polyurethane layer portion P10 formed on the first matte film M10 in the step of FIG. 3A, and the second polyurethane layer portion P20 formed on the second matte film M20 in the step of FIG. 3B is bonded to each other with the intervening of an intermediate layer portion P15 therebetween, so that a bonding structure in which the intermediate layer portion P15 and the second polyurethane layer portion P20 are sequentially disposed on the first polyurethane layer portion P10 may be formed.

For example, a bonding structure as shown in FIG. 3C may be formed by applying a solution for forming an intermediate layer portion on the first polyurethane layer portion P10 formed on the first matte film M10, and bonding the second polyurethane layer portion P20 on the applied solution for forming the intermediate layer portion. Here, the solution for forming the intermediate layer portion may be a kind of adhesive solution, and the intermediate layer portion P15 formed therefrom may be a kind of bonding layer or adhesive layer. The adhesive layer may include a urethane-based polymer. The urethane-based polymer may be formed by curing a thermosetting urethane resin solution. The urethane-based polymer may include thermosetting polyurethane.

The intermediate layer portion P15 may have the same material composition as that of the first polyurethane layer portion P10. Also, the intermediate layer portion P15 may have the same material composition as that of the second polyurethane layer portion P20. Furthermore, the first polyurethane layer portion P10 and the second polyurethane layer portion P20 may have the same material composition. In this case, the first polyurethane layer portion P10, the intermediate layer portion P15, and the second polyurethane layer portion P20 may constitute one integrated layer structure (a base layer structure). However, the intermediate layer portion P15 may have a material composition different from that of at least one of the first polyurethane layer portion P10 and the second polyurethane layer portion P20.

Referring to FIG. 3D, the first matte film (M10 in FIG. 3c) may be removed from the first polyurethane layer portion P10, and the second matte film (M20 in FIG. 3c) may be removed from the second polyurethane layer portion P20. The product of FIG. 3D may be the same as the release film described with reference to FIG. 1. The manufacturing method of the release film described with reference to FIGS. 3A to 3D may be referred to as a manufacturing method of the release film based on a ‘bonding method’.

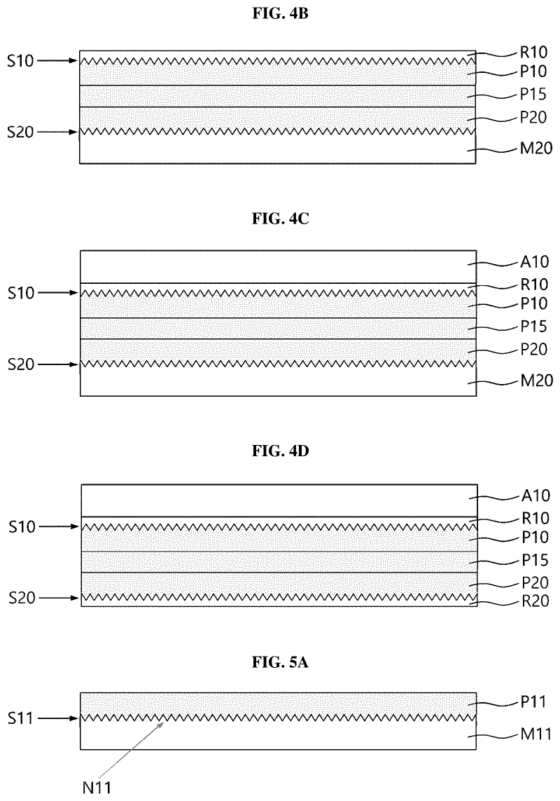

FIG. 4A to FIG. 4D are cross-sectional diagrams illustrating a method for manufacturing a release film for a semiconductor package according to another embodiment of the present invention.

Referring to FIG. 4A, a bonding structure having the same structure as that of FIG. 3C may be provided. However, in FIG. 4A, the bonding structure of FIG. 3C is shown as an upside-down type. Herein, the bonding structure is only partially illustrated with a short length, but in reality, the bonding structure may have a length (a fairly long length) which may be rolled into a roll.

Referring to FIG. 4B, the first matte film (M10 in FIG. 4A) may be removed from the first polyurethane layer portion P10, and a first release agent R10 may be applied on the first surface S10 of the first polyurethane layer portion P10. The first release agent R10 may be, for example, a release agent solution containing silicone or fluorine.

Referring to FIG. 4C, an adhesive film A10 may be attached on the first release agent R10. The adhesive film A10 may be a temporary film, and may have an adhesive strength of a degree for easy attachment and detachment. In one embodiment, in the steps of FIGS. 4B and 4C, while removing the first matte film (M10 of FIG. 4A) from the first polyurethane layer portion P10, the first release agent R10 may be applied to the surface S10 of the first polyurethane layer portion P10 (FIG. 4B), and the adhesive film A10 may be attached on the first release agent R10 (FIG. 4C).

Referring to FIG. 4D, while removing the second matte film (M20 in FIG. 4C) from the second polyurethane layer portion P20, a second release agent R20 may be applied on the second surface S20 of the second polyurethane layer portion P20. The second release agent R20 may be the same composition material as that of the first release agent R10. The structure (a film member) of FIG. 4Cc may be rolled and stored as a form of a roll. If necessary, the structure (a film member) of FIG. 4C may be cut (i.e., slitting) to an appropriate width, and the adhesive film A10 may be removed.

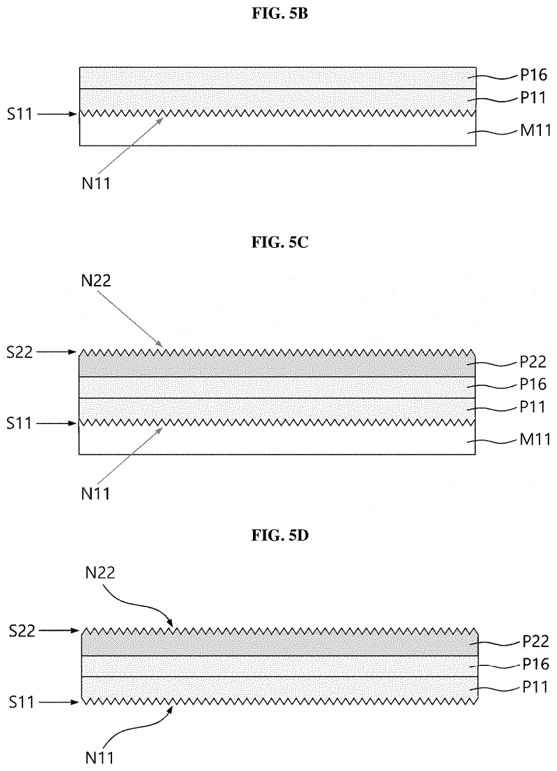

FIG. 5A to FIG. 5D are cross-sectional diagrams illustrating a manufacturing method of a release film for a semiconductor package according to another embodiment of the present invention.

Referring to FIG. 5A, a first solution for forming polyurethane may be applied on a matte film M11, and a first polyurethane layer portion P11 may be formed from the first solution for forming polyurethane. The matte film M1 may be, for example, a PET film, but the material of the matte film M11 is not limited thereto and may vary.

When the first solution for forming polyurethane is applied on a matte-treated surface (an upper surface in the drawing) of the matte film M11 and a cured first polyurethane layer portion P11 is formed therefrom, a first fine unevenness N11 may be formed on a first surface S11 of the first polyurethane layer portion P11 bonded to the matte film M11. The first solution for forming polyurethane may include a urethane-based source material, a solvent, and a curing agent, etc.

Referring to FIG. 5B, a solution for forming an intermediate layer portion may be applied on the first polyurethane layer portion P11, and an intermediate layer portion P16 may be formed from the solution for forming the intermediate layer portion. The solution for forming the intermediate layer may be the same as or similar to the first solution for forming polyurethane. Accordingly, the intermediate layer portion P16 may have the same material composition as that of the first polyurethane layer portion P11. The formation of the intermediate layer portion P16 may be referred to as a process for increasing the thickness of the first polyurethane layer portion P11 to an appropriate height.

Referring to FIG. 5C, a second solution for forming polyurethane may be applied on the intermediate layer portion P16, and a second polyurethane layer portion P22 may be formed from the second solution for forming polyurethane. The second polyurethane layer portion P22 may have a second surface S22 opposite to the intermediate layer portion P16, and the second surface S22 may have a second fine unevenness N22 at least for improving releasability.

The second polyurethane layer portion P22 may have a material composition different from that of the first polyurethane layer portion P11 and the intermediate layer portion P16. The second polyurethane layer portion P22 may further include an inorganic material, and the second fine unevenness N22 may be formed on the second surface S22 of the second polyurethane layer portion P22 by the inorganic material. More specifically, the second polyurethane layer portion P22 may include a base layer portion made of thermosetting polyurethane and an inorganic material contained in the base layer portion, and the second fine unevenness N22 may be formed by the inorganic material. The inorganic material may, for example, have a form of a particle (a plurality of particles). Furthermore, the inorganic material may include, for example, at least one of silica, calcium carbonate (CaCO₃) and barium sulfate (BaSO₄). However, the type of inorganic material which may be used in the embodiment of the present invention is not limited to the above-mentioned materials, and may be variously changed.

The second solution for forming polyurethane used to form the second polyurethane layer portion P22 may be a solution in which the inorganic material is mixed with the same solution as the first solution for forming polyurethane described with reference to FIG. 5A.

Referring to FIG. 5D, the matte film (M11 in FIG. 5C) may be removed from the first polyurethane layer portion P11. The result of FIG. 5D may be the same as the release film described with reference to FIG. 2. The manufacturing method of the release film described in FIGS. 5A to 5D may be referred to as a method of manufacturing the release film by the ‘repeat coating method’.

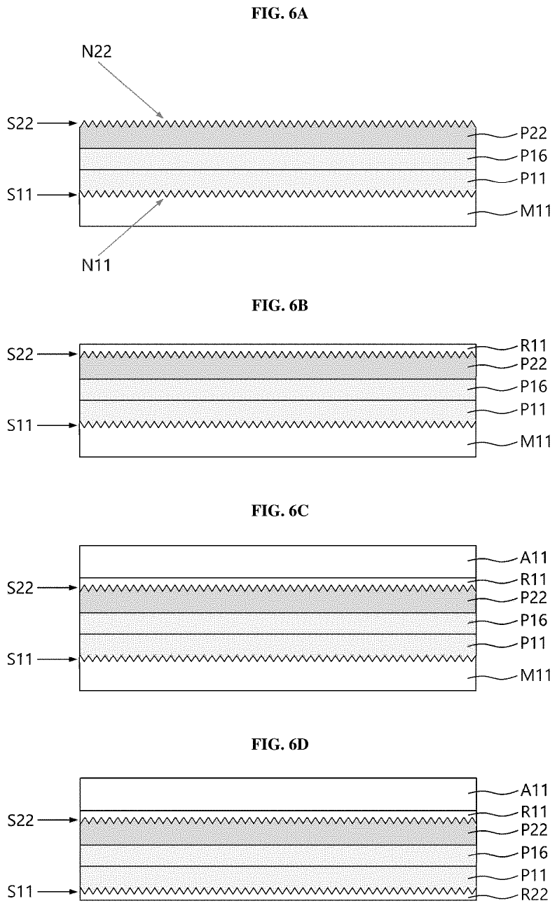

FIG. 6A to FIG. 6D are cross-sectional diagrams illustrating a manufacturing method of a release film for a semiconductor package according to another embodiment of the present invention.

Referring to FIG. 6A, the same structure as that of FIG. 5C may be provided. Here, although the structure (a film structure) is only partially illustrated in a short length, in fact, the structure (a film structure) may have a length capable of being rolled into a roll form.

Referring to FIG. 6B, a first release agent R11 may be applied to a second surface S22 of the second polyurethane layer portion P22. The first release agent R11 may be, for example, a release agent solution containing silicone or fluorine.

Referring to FIG. 6C, an adhesive film All may be attached on the first release agent R11. The adhesive film All may be a temporary film, and may have an adhesive strength of a degree for easy attachment and detachment.

Referring to FIG. 6D, while removing the matte film (M11 in FIG. 6C) from the first polyurethane layer portion P11, a second release agent R22 may be applied on a first surface S11 of the first polyurethane layer portion P11. The second release agent R22 may be the same material as the first release agent R11. The structure (a film member) of FIG. 6D may be rolled up and stored as a form of a roll. If necessary, the structure (a film member) of FIG. 6D may be cut (i.e., slitting) to an appropriate width, and the adhesive film A11 may be removed.

In the manufacturing method of the release film described with reference to FIGS. 5A to 5D, the formation of the intermediate layer portion P16 may be excluded in some cases. That is, the second polyurethane layer portion P22 may be formed on the first polyurethane layer portion P11 without forming the intermediate layer portion P16 in the step of FIG. 5B. In this case, the second polyurethane layer portion P22 may be in direct contact (be bonded) with the upper surface of the first polyurethane layer portion P11. Such a modified structure may be equally applied to the manufacturing method of the release film described with reference to FIGS. 6A to 6D.

In FIG. 3A to FIG. 3D, FIG. 4A to FIG. 4D, FIG. 5A to FIG. 5D, and FIG. 6A to FIG. 6D, only some of the film members are shown in short lengths for convenience, but in reality, the film members may have a length which may be rolled as a roll form, and a process suitable for it may be applied.

For example, in the manufacturing methods of FIGS. 3A to 3D and FIGS. 4A to 4D, the forming the first polyurethane layer portion P10, the forming the second polyurethane layer portion P20, the forming the bonding structure, and the like may be performed by using a roll-to-roll process. In this case, for example, the forming the first polyurethane layer portion P10, the forming the second polyurethane layer portion P20, and the forming the bonding structure, etc. may be performed by using any one of a micro-gravure coater, a comma coater and a slot die coater.

Similarly, in the manufacturing methods of FIGS. 5A to 5D and FIGS. 6A to 6D, the forming the first polyurethane layer portion P11, the forming the intermediate layer portion P16, the forming the second polyurethane layer portion P22, and the like may be performed by using a roll-to-roll process. In this case, for example, the forming the first polyurethane layer portion P11, the forming the intermediate layer portion P16, and the forming the second polyurethane layer portion P22, etc. may be performed by using any one of a micro-gravure coater, a comma coater and a slot die coater.

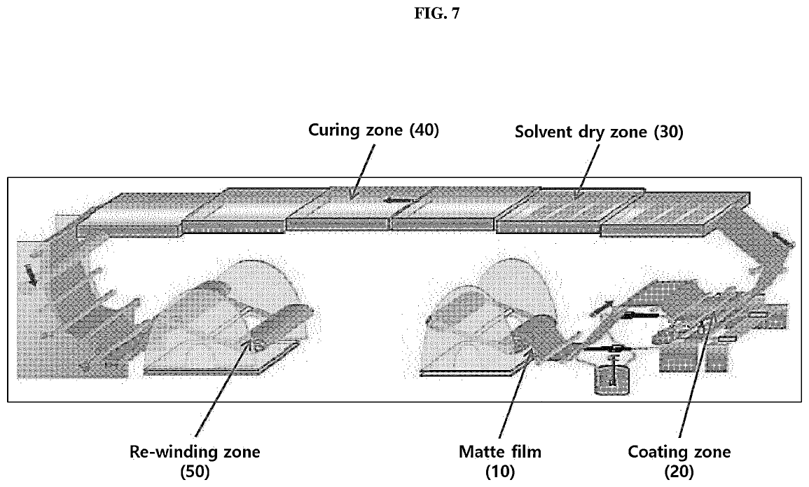

FIG. 7 is a diagram for explaining an apparatus applicable to a manufacturing method of a release film for a semiconductor package according to an embodiment of the present invention, and a manufacturing process using the same.

Referring to FIG. 7, an apparatus applicable to the manufacturing method of a release film according to an embodiment of the present invention may be a coating apparatus using a roll-to-roll process. For example, the apparatus may include a portion on which a matte film 10 is wound as a roll form is mounted, and the apparatus may be configured so that the matte film 10 is transported while one end of the matte film 10 is being pulled. The apparatus may include a coating zone 20 for applying a solution for forming polymer on the transported matte film 10, a dry zone 30 for removing (drying) a solvent from the applied solution for forming polymer (a polymer-forming film), and a curing zone 40 for curing the applied solution for forming polymer (a polymer-forming film). Curing the curing zone 40 may include curing using heat or curing using ultraviolet (UV) light, or both of curing using heat and curing using ultraviolet (UV). Furthermore, the apparatus may include a re-winding zone 50 for winding the matte film 10 on which the coating operation is completed in a form of a roll again.

The configuration of the apparatus shown in FIG. 7 is merely exemplary, and may be variously changed. As an example, in FIG. 7, a case of a curing the film for forming the polymer in the apparatus has been illustrated and described, but the film for forming the polymer may be cured by drying the film member in the form of a roll which has been rewound under a predetermined drying condition. This may be referred to as ‘cure hardening’ or ‘dry curing after winding’. The curing, for example, may be carried out at a temperature of about 50° C. drying conditions for 24 hours or more. However, this is exemplary, and drying conditions may be variously changed. The curing method which may be applied when manufacturing the release film according to the embodiment of the present invention may include not only the curing method in the coating apparatus, but also the cure hardening (dry curing after winding) method described above.

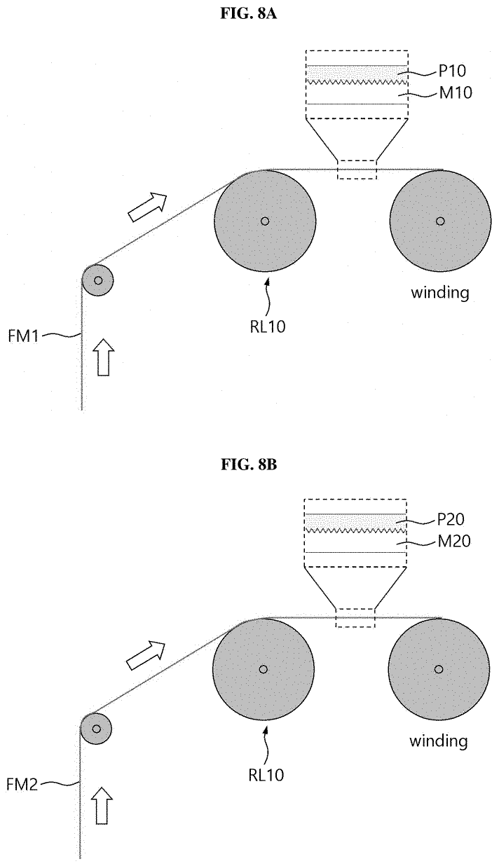

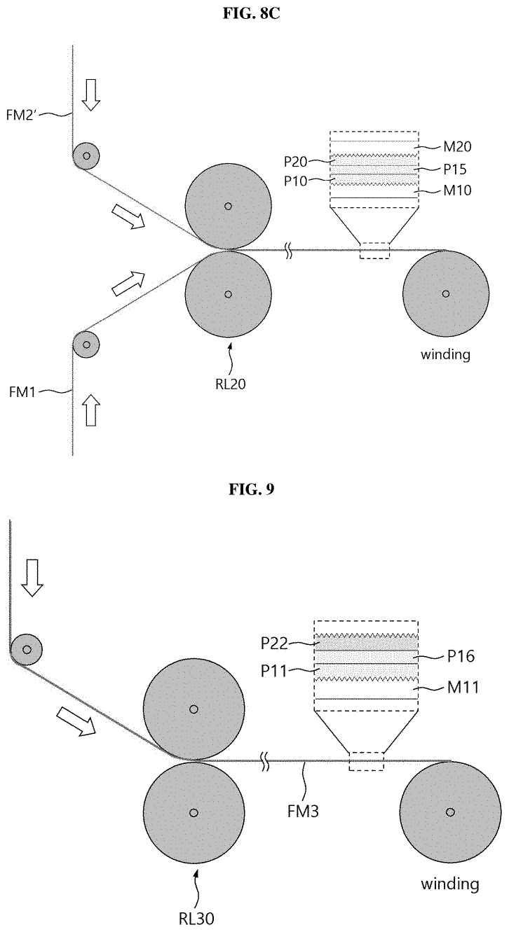

FIG. 8A to FIG. 8D are diagrams for explaining a manufacturing method of a release film for a semiconductor package according to another embodiment of the present invention.

Referring to FIG. 8A, a first film member FM1 may be transported by using a plurality of roll members RL10 to be wound as a roll shape. In an embodiment, the first film member FM1 may have a film configuration as described with reference to FIG. 3A. The first film member FM1 may include a first matte film M10 and a first polyurethane layer portion P10 formed thereon.

Referring to FIG. 8B, a second film member FM2 may be transported by using the plurality of roll members RL10 to be wound as a roll shape. Here, the second film member FM2 may have a film configuration as described with reference to FIG. 3B. In an embodiment, the second film member FM2 may include a second matte film M20 and a second polyurethane layer portion P20 formed thereon.

Referring to FIG. 8C, the first film member FM1 of FIG. 8A and the second film member FM2 of FIG. 8B may be bonded by using a plurality of roll members RL20. The reference numeral FM2′ in FIG. 8C denotes a film member in which a solution for forming an intermediate layer portion (i.e., a resin solution for adhesion) is applied on the second polyurethane layer portion P20 of the second film member FM2. As a result, the same structure as described in FIG. 3C, that is, a bonding structure wherein the first polyurethane layer portion P10 formed on the first matte film M10 and the second polyurethane layer portion P20 formed on the second matte film M20 are bonded to each other with interposing the intermediate layer portion P15 may be formed.

FIG. 9 is a diagram for explaining a manufacturing method of a release film for a semiconductor package according to another embodiment of the present invention.

Referring to FIG. 9, a film member FM3 may be transported by using a plurality of roll members RL30 to be wound as a roll shape. Here, the film member FM3 may have the same structure as the film member of FIG. 5C. In one embodiment, the film member FM3 may include a first polyurethane layer portion P11, an intermediate layer portion P16, and a second polyurethane layer portion P22 sequentially coated on a matte film M11.

In the manufacturing methods described with reference to FIGS. 8A to 8C and FIG. 9, the plurality of roll members RL10, RL20, RL30 corresponds to a portion of the manufacturing apparatus (a coating apparatus), and they are merely exemplary, and the configuration or arrangement of the plurality of roll members RL10, RL20, RL30 may be variously changed.

Additionally, according to another embodiment of the present invention, a release film may be manufactured without using a matte film. For example, a first polyurethane layer portion may be formed on a general PET releasable film (carrier film) rather than a matte film, and then, a second polyurethane layer portion including an inorganic filler may be formed thereon. Next, the PET releasable film (carrier film) may be removed from the first polyurethane layer portion, and then a third polyurethane layer portion including an inorganic filler may be formed on the surface of the first polyurethane layer portion which is exposed by the removal of the PET releasable film (a carrier film). In this case, the first polyurethane layer portion may have the same material configuration as the intermediate layer portions P15 and P16 of FIGS. 1 and 2, and the second and third polyurethane layer portions may have the same surface roughness and material composition as the second polyurethane layer portion P22 of FIG. 2. Accordingly, the first polyurethane layer portion may be referred to as an ‘intermediate layer portion’. Furthermore, various structural modifications and changes in manufacturing methods may be possible.

Hereinafter, a manufacturing process of a polyurethane layer which may be applied to the manufacturing method of the release film for a semiconductor package according to embodiments of the present invention will be described in more detail.

The number average molecular weight (or weight average molecular weight) of the polyurethane resin used in the embodiment of the present invention may be about 50000 to 500000. Urethane (polyurethane) may be obtained by reaction of polyol and isocyanate, and may be manufactured by controlling the reaction rate and molecular weight using a catalyst.

As the polyol, one or a mixture of two or more products having a molecular weight of about 500 to 7000 may be used as a raw material. As the ether-based polyol, polypropylene glycol, modified polypropylene glycol, and polytetramethylene glycol (PTMG) may be used. As the polyester-based polyol, polyethylene glycol having a molecular weight in the range of about 500 to 7000, adipate-based polyester polyol which is a polycarbonate-based polycondensation system, and a lactone-based polyol of a ring-opening polymerization base may be used. Furthermore, one or two or more of polybutadiene glycol and acryl-based polyol may be mixed and used. However, the above materials are exemplary, and the present application is not limited thereto.

As the isocyanate material, various diisocyanate-based materials may be used. For example, PPDI may be used as p-phenylene diisocyanate with a molecular weight of 160.1, TDI including isomer of toluene-diisocyanate may be used as toluene-diisocyanate with a molecular weight of 174.2, NDI may be used as 1,5-naphthalene diisocyanate with a molecular weight of 210.2, HDI may be used as 1,6-hexamethylene diisocyanate with a molecular weight of 168.2, MDI may be used as 4,4′-diphenylmethane diisocyanate with a molecular weight of 250.3, IPDI may be used as isoporon diisocyanate with a molecular weight of 222.3, and H12MDI may be used as cyclohexylmethane diisocyanate with a molecular weight of 262 may be used. However, the above materials are exemplary, and the present application is not limited thereto.

Furthermore, a chain extender material may be additionally used to the polyol and isocyanate. The chain extender may serve to increase the molecular weight of the polyurethane and impart various functionalities. One to two or more of the chain extenders may be mixed and used. As the chain extender, ethylene glycol-based material, propylene glycol-based material, butadiene glycol-based material, polyhydric alcohol including silicone, polyhydric alcohol including fluorine, etc. may be used. However, the above materials are exemplary, and the present application is not limited thereto.

As the catalyst, various organic tin-based materials and organic bismuth-based materials may be used. The organotin-based material (an organotin-based compound) may include, for example, dibutyltin dilaurate, stannous octoate, dibutyltin diacetate, dibutyltin dimercaptide, and the like. Here, dibutyltin dilaurate is (CH₃CH₂CH₂CH₂)₂Sn[CH₃(CH₂)₁₀COO]₂, stannous octoate is Sn[C₇H₁₅COO]₂, dibutyltin diacetate is (CH₃CH₂CH₂CH₂)₂Sn[CH₃COO]₂, dibutyltin dimercaptide is (CH₃CH₂CH₂CH₂)₂Sn[SC₁₂H₂₅]. The organic bismuth-based material (an organic bismuth-based compound) may have various molecular weights, and may include, for example, a carboxylate-based catalyst material containing bismuth. Here, the carboxylate-based catalyst material may contain about 9% to about 45% of bismuth. However, the above materials are exemplary, and the present application is not limited thereto.

As a solvent for making a polyurethane resin solution, for example, various acetone solvents and the like including DMF (dimethylformamide), DEF (diethylformamide), DMSO (dimethylsulfoxaide), DMAC (dimethylacetamide), toluene, ethyl acetate (EA), methyl ethyl ketone, including may be used. However, the above materials are exemplary, and the present application is not limited thereto.

After preparing a resin solution for preparing polyurethane in which the polyol, isocyanate, solvent, etc. are mixed, a polymer cured product having various crosslinking densities may be formed by a reaction using a melamine-based curing agent, its catalyst, and an isocyanate-based curing agent polymerized with various molecular weights. In this case, a curing method using heat may be applied.

The composition of the curable polyurethane which may be applied to an embodiment of the present invention will be described as follows.

In the polyurethane composition, as a first material for the urethane reaction, polyol such as a polyester-based polyol (e.g., molecular weight 500-7000), polyether-based polyol (e.g., molecular weight 200-3000) or polycarbonate-based polyol (e.g., molecular weight 500-8000) may be applied, and an isocyanate-based material may be applied as a second material for the urethane reaction. As the isocyanate-based material, various isocyanate types containing a yellowing benzene-ring, and various isocyanates including hexamethylene-base, isophorone-base and cyclohexylmethane-base as the non-yellowing may be used. Furthermore, a chain extender may be further used to increase the molecular weight of the polyurethane. As the chain extender, ethylene glycol-based materials, propylene glycol-based materials, butadiene glycol-based materials, polyhydric alcohols including silicone, polyhydric alcohols including fluorine, etc. may be used, and the chain extender is reacted with urethane so that the molecular weight of the polyurethane may be increased.

As other additives, a leveling agent, an antifoaming agent, a curing agent, and the like may be further used. As the leveling agent, a modified polyether-based leveling agent including a silicone-based, fluorine-based or non-silicone-based leveling agent may be used, and the leveling agent may be used in a mixture of about 0.1 wt % to 5 wt %. The antifoaming agent is for a defoaming function, and for example, a silicone-based or non-silicone-based antifoaming agent may be used. The antifoaming agent may be used in a mixture of about 0.1 wt % to 5 wt %. Furthermore, as a curing agent for the curing reaction of the prepared polyurethane, a melamine-based curing agent and an isocyanate-based curing agent polymerized with several molecules may be used. Furthermore, the curing reaction may be accelerated in the presence of an acid catalyst.

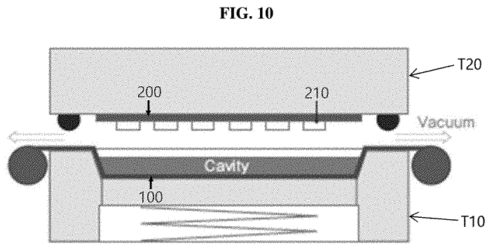

FIG. 10 is a diagram for explaining a molding process of a semiconductor package to which a release film for a semiconductor package according to an embodiment of the present invention is applied.

Referring to FIG. 10, a molding process of a semiconductor package may be performed by using the release film 100 according to an embodiment of the present invention. The molding apparatus may include a first molding tool T10 and a second molding tool T20 facing the first molding tool T10. The first molding tool T10 may be a lower molding tool, and the second molding tool T20 may be an upper molding tool.

A predetermined concave portion (a cavity region) may be provided in the first molding tool T10, and the release film 100 may be placed to cover the concave portion. The release film 100 may be sucked so as to be in close contact with the surface of the concave portion by a vacuum adsorption method (i.e., a suction method). A substrate 200 having a plurality of semiconductor device units 210 formed thereon may be disposed on a lower surface of the second molding tool T20. A molding material (e.g., EMC) (not shown) may be disposed on a portion of the release film 100 of the concave portion (a cavity region). A heating process for melting the molding material, and a vacuum compression process for attaching the molten molding material to the side of the semiconductor device unit 210 may be performed.

The release film 100 according to the embodiment of the present invention may have excellent mechanical properties which may withstand high temperature and high pressure conditions without rupture during the molding process of a semiconductor package, and also have excellent releasability (peelability). In particular, since the release film 100 includes a thermosetting material, it may have superior mechanical properties than a conventional release film based on a thermoplastic material. Therefore, the release film 100 according to the embodiment of the present invention may not rupture even under conditions of high temperature and high pressure. Furthermore, when the release film 100 is fixed by sucking the film 100 into the cavity of the first molding tool T10 by an adsorption method (i.e., a suction method), at a predetermined high temperature (e.g., about 165° C.), the instantaneous stretching property may be excellent. Accordingly, a problem in which the release film 100 is ruptured may be prevented. Furthermore, since the release film 100 according to the embodiment of the present invention has low permeability to fume-gas generated during the molding process, mold contamination and productivity decrease problems which are generated due to fume-gas may be prevented. Therefore, when the release film 100 according to the embodiment of the present invention is used, the defect rate of the semiconductor package may be lowered, productivity may be improved, and the characteristics of the manufactured package may be improved.

Additionally, since the release film 100 according to the embodiment of the present invention has a fine unevenness (refer to N10 of FIG. 1) on its lower surface, when fixing the release film 100 into the cavity of the first molding tool T10 by suction, it is possible to prevent the problem that bubbles are generated on the lower surface of the release film 100, and at the same time, it is possible to improve the releasability (peelability). Furthermore, the release film 100 may also have a fine unevenness (refer to N20 of FIG. 1) on the upper surface thereof, and the fine unevenness formed on the upper surface may be transferred to the bottom surface of the molding material (e.g., EMC). Accordingly, a fine unevenness may be formed on the lower surface of the molding layer (e.g., EMC layer) of the semiconductor package, and the fine unevenness of the molding layer may serve to suppress the adhesion of foreign substances, and suppress the formation of stains and marks. Furthermore, the fine unevenness formed on the upper surface of the release film 100 may serve to improve the releasability (peelability).

In the present specification, preferred embodiments of the present invention have been disclosed, and although specific terms are used, these are only used in a general sense to easily describe the technical contents of the present invention and to help the understanding of the present invention, and are not used to limit the scope of the present invention. It will be apparent to those of ordinary skill in the art to which the present invention pertains that other modifications based on the technical spirit of the present invention may be implemented Furthermore to the embodiments disclosed herein. It will be appreciated to those of ordinary skill in the art that release films for a semiconductor package and methods for manufacturing the same according to the embodiments described with reference to FIGS. 1 to 10 may be variously substituted, changed and modified without departing from the spirit of the present invention. Therefore, the scope of the invention should not be determined by the described embodiments, but should be determined by the technical concepts described in the claims.

1. A release film for a semiconductor package comprising:
a first polyurethane layer portion; and
a second polyurethane layer portion disposed on the first polyurethane layer portion,
wherein the first polyurethane layer portion has a first surface opposite to the second polyurethane layer portion, and the first surface has a first fine unevenness for releasability,
wherein the second polyurethane layer portion has a second surface opposite to the first polyurethane layer portion, and the second surface has a second fine unevenness for releasability,
wherein the first and second polyurethane layer portions include a thermosetting polyurethane having a cross-linkage.

2. The release film of claim 1, wherein the first surface has a surface roughness of 5 μm or more due to the first fine unevenness, and the second surface has a surface roughness of 5 μm or more due to the second fine unevenness.

3. The release film of claim 1, further comprising an intermediate layer portion disposed between the first polyurethane layer portion and the second polyurethane layer portion, wherein the intermediate layer portion is an adhesive layer.

4. (canceled)

5. The release film of claim 3, wherein the adhesive layer includes a urethane-based polymer.

6. The release film of claim 3, wherein the intermediate layer portion has the same material composition as the first polyurethane layer portion.

7. The release film of claim 3, wherein the first polyurethane layer portion and the second polyurethane layer portion have the same material composition.

8. The release film of claim 1,
wherein the second polyurethane layer portion has a material composition different from that of the first polyurethane layer portion,
wherein the second polyurethane layer portion further includes an inorganic material, and the second fine unevenness is formed on the second surface of the second polyurethane layer portion by the inorganic material.

9. (canceled)

10. The release film of claim 1,
wherein the release film has a thickness in a range of 30 to 120 μm,
wherein a thickness of the first polyurethane layer portion is 10 to 70 μm, and a thickness of the second polyurethane layer portion is 10 to 70 μm.

11. (canceled)

12. A manufacturing method of a release film for a semiconductor package comprising:
applying a first solution for forming polyurethane on a first matte film, and forming a first polyurethane layer portion from the first solution for forming polyurethane;
applying a second solution for forming polyurethane on a second matte film, and forming a second polyurethane layer portion from the second solution for forming polyurethane;
mutually bonding the first polyurethane layer portion formed on the first matte film and the second polyurethane layer portion formed on the second matte film while interposing an intermediate layer portion therebetween, and forming a bonding structure in which the intermediate layer portion and the second polyurethane layer portion are sequentially disposed on the first polyurethane layer portion; and
removing the first matte film from the first polyurethane layer portion, and removing the second matte film from the second polyurethane layer portion,
wherein the first polyurethane layer portion has a first surface opposite to the intermediate layer portion, and the first surface has a first fine unevenness for releasability,
wherein the second polyurethane layer portion has a second surface opposite to the intermediate layer portion, and the second surface has a second fine unevenness for releasability,
wherein the first and second polyurethane layer portions include thermosetting polyurethane having a cross-linkage.

13. The manufacturing method of a release film of claim 12,
wherein the forming the first polyurethane layer portion, the forming the second polyurethane layer portion, and the forming the bonding structure are performed by using a roll-to-roll process,
wherein the forming the first polyurethane layer portion, the forming the second polyurethane layer portion, and the forming the bonding structure are performed by using any one of a micro-gravure coater, a comma coater and a slot die coater.

14. (canceled)

15. The manufacturing method of a release film of claim 12,
wherein the intermediate layer portion is an adhesive layer,
wherein the adhesive layer includes a urethane-based polymer.

16. (canceled)

17. The manufacturing method of a release film of claim 12, wherein the intermediate layer portion has a material composition different from that of the first polyurethane layer portion.

18. The manufacturing method of a release film of claim 12, wherein the intermediate layer portion may have the same material composition as the first polyurethane layer portion.

19. The manufacturing method of a release film of claim 12, further comprising:
applying a first release agent to the first surface of the first polyurethane layer portion and attaching an adhesive film while removing the first matte film from the first polyurethane layer portion; and
applying a second release agent to the second surface of the second polyurethane layer portion while removing the second matte film from the second polyurethane layer portion.

20. A manufacturing method of a release film for a semiconductor package, comprising:
applying a first solution for forming polyurethane on a matte film, and forming a first polyurethane layer portion from the first solution for forming polyurethane;
applying a second solution for forming polyurethane on the first polyurethane layer portion, and forming a second polyurethane layer portion from the second solution for forming polyurethane; and
removing the matte film from the first polyurethane layer portion,
wherein the first polyurethane layer portion has a first surface opposite to the second polyurethane layer portion, and the first surface has a first fine unevenness for releasability,
wherein the second polyurethane layer portion has a second surface opposite to the first polyurethane layer portion, and the second surface has second unevenness for releasability,
wherein the first and second polyurethane layer portions include thermosetting polyurethane having a cross-linkage.

21. The manufacturing method of a release film of claim 20,
wherein the forming the first polyurethane layer portion and the forming the second polyurethane layer portion are performed by using a roll-to-roll process,
wherein the forming the first polyurethane layer portion and the forming the second polyurethane layer portion are performed by using any one of a micro-gravure coater, a comma coater, and a slot die coater.

22. (canceled)

23. The manufacturing method of a release film of claim 20, further comprising applying a solution for forming an intermediate layer portion on the first polyurethane layer portion, and forming an intermediate layer portion from the solution for forming the intermediate layer portion after the forming the first polyurethane layer portion,
wherein the second polyurethane layer portion is formed on the intermediate layer portion.

24. The manufacturing method of a release film of claim 23, wherein the intermediate layer portion has the same material composition as the first polyurethane layer portion.

25. The manufacturing method of a release film of 23,
wherein the second solution for forming polyurethane includes an inorganic material, and the second fine unevenness is formed on the second surface of the second polyurethane layer portion by the inorganic material,
wherein the inorganic material includes at least one of silica, calcium carbonate (CaCO₃) , and barium sulfate (BaSO₄).

26. (canceled)

27. The manufacturing method of a release film of claim 20, further comprising:
applying a first release agent to the second surface of the second polyurethane layer portion and attaching an adhesive film; and
applying a second release agent to the first surface of the first polyurethane layer portion while removing the matte film from the first polyurethane layer portion.
